(19) United States
(12) Patent Application Publication
(10) Pub. No.: US 2026/0231326 A1
(43) Pub. Date: Aug. 6, 2026

(54) THROUGH HOLE VIA WITH BLIND VIA FOR CABLE ATTACHMENT

(71) Applicant: Teradyne, Inc., North Reading, MA (US)

(72) Inventors: Frank Parrish, Simi Valley, CA (US); Dustin J. Hunt, Woodland Hills, CA (US)

(73) Assignee: Teradyne, Inc., North Reading, MA (US)

(21) Appl. No.: 19/046,401

(22) Filed: Feb. 5, 2025

(51) Int. Cl. H05K 1/11; H05K 1/18; H05K 3/00; H05K 3/34; H05K 3/42

(52) U.S. Cl. CPC H05K 1/115; H05K 1/183; H05K 3/0094; H05K 3/34; H05K 3/42; H05K 2201/10356; H05K 2201/10378

(57) ABSTRACT

Via structures for interposers are described. The via structures may include a counterbore and a plurality of filled vias positioned in connection with the counterbore to provide electrical connection from one side of an interposer to the other side of the interposer. The plurality of filled vias include three filled vias in some embodiments. The three filled vias may be off-center from the center of the counterbore in some embodiments.

### BACKGROUND

### Field

The present disclosure relates to through hole vias with blind vias for cable attachment.

### Related Art

Some printed circuit boards (PCB) have through-hole vias that provide electrical connection from one side of the PCB to another side of the PCB. The PCBs are sometimes positioned within a stack of electrical components to provide electrical connection within a system such as automatic test equipment (ATE).

### BRIEF SUMMARY

According to an aspect of the technology, an apparatus is provided for facilitating reliable electrical connection through an interface printed circuit board (PCB). The apparatus comprises the interface PCB, which comprises a first side, and a second side. The apparatus further comprises an interposer pad disposed on the first side of the interface PCB. The apparatus further comprises a plated counterbore disposed on the second side of the interface PCB opposite the interposer pad. The apparatus further comprises a plurality of filled vias connecting the interposer pad to the plated counterbore through the interface PCB.

According to an aspect of the technology, a method is provided for manufacturing an apparatus for facilitating reliable electrical connection through an interface printed circuit board (PCB) having a first surface and a second surface. The method comprises opening a plurality of through holes in the interface PCB, wherein the first surface is parallel to the second surface, and the plurality of through holes extend from the first surface through to the second surface. The method further comprises forming a plurality of vias by plating the plurality of through holes with an electrically conductive first material. The method further comprises filling the plurality of vias with a filler material. The method further comprises opening a counterbore on the first surface such that a first end of each of the plurality of vias interfaces with the counterbore. The method further comprises plating the counterbore with one or more electrically conductive layers. The method further comprises disposing an electrically conductive interposer pad on the second surface opposite the counterbore such that a second end of each of the plurality of vias interfaces with the interposer pad.

According to an aspect of the technology, a system is provided, the system being for providing electrical interconnection in automatic test equipment (ATE). The system comprises a device, a plurality of cables, and an interface printed circuit board (PCB) disposed between the device and the plurality of cables. The interface PCB comprises an array of interconnect structures, each interconnect structure comprising an interposer pad, a plated counterbore, and a plurality of filled vias connecting the interposer pad to the plated counterbore. The device includes a plurality of electrical connections coupled to the interposer pads of the array of interconnect structures. Each cable of the plurality of cables is coupled to a respective counterbore of the array of interconnect structures.

### BRIEF DESCRIPTION OF DRAWINGS

Various aspects and embodiments of the technology will be described with reference to the following figures. It should be appreciated that the figures are not necessarily drawn to scale. Items appearing in multiple figures are indicated by the same reference number in all the figures in which they appear.

FIGS. 1A-1C are perspective views of an apparatus for facilitating reliable electrical connection according one embodiment of the present technology.

FIG. 2 is a perspective view of an apparatus according to another embodiment of the present technology.

FIGS. 3A-3B are perspective views of apparatuses according to additional embodiments of the present technology.

FIG. 4 is a flow chart illustrating a method for manufacturing an apparatus according to some embodiments of the present technology.

FIGS. 5A-5C are perspective views of an apparatus at different stages of manufacture according to steps illustrated in FIG. 4.

FIG. 6 is a cross-section of an apparatus according to some embodiments of the present technology.

FIG. 7 is a cross-section of an apparatus comprising a plurality of interconnect structures according to some embodiments of the present technology.

FIG. 8 is a perspective view of an apparatus according to some embodiments of the present technology.

FIG. 9 is a perspective view of a portion of the apparatus of FIG. 8.

FIG. 10 is a perspective view of the apparatus of FIG. 8 with additional external components made visible.

### DETAILED DESCRIPTION

The development and testing of modern electrical components, such as may be performed by electrical test equipment comprising ATE, requires a high density of electrical connections (e.g. to provide for the large number of connections of modern electrical systems with or through a component having a certain surface area). Often, electrical connections must be made through a PCB (e.g. an interface PCB). For example, ATE systems may comprise structures in which a cable (e.g. comprising a wire) is electrically connected through an interface PCB to an electrical pin.

In such a configuration, the cable may be connected (e.g. soldered) to a counterbore in the interface PCB. The counterbore is, for example, a drilled hole of a diameter which is larger than that of a deeper hole originating from an opposite side of the interface PCB. The deeper hole originating from the opposite side of the interface PCB may, for purposes of explanation, be referred to herein as a “primary hole,” or for simplicity sometimes simply a “hole.” The primary hole of the counterbore may be a via (e.g. a blind via) which is electrically connected to the counterbore and to an electrically conductive pad disposed on a face of the interface PCB opposite to the counterbore. Thus, the counterbore and via enable the cable on one side of the interface PCB to electrically connect to a pin which contacts the pad on the opposite side of the interface PCB.

Manufacturing small-scale components (e.g. the counterbore and via disposed in an interface PCB) which facilitate electrical connections at the density of electrical contacts required may require specialized techniques intended to provide for reliable electrical connection (e.g. between a cable and a pin through an interface PCB). Examples of these techniques include electroless copper plating and copper electroplating. However, these techniques are imperfect. When plating a counterbore with copper (or any other suitable material), for instance, the resultant conductive coating may be flawed (e.g. uneven, not complete, or too thin) due, for example, to bubbles (e.g. pockets of gas which persist when a counterbore is submerged during electroplating due to the geometry and chemistry of the counterbore). These imperfections may be particularly likely to occur at the bottom center of the counterbore, and thus may be likely to disrupt electrical connection with a via joined thereat.

As noted above, modern electrical systems may require many connections (e.g. many counterbores with respective vias). However, the presence of even a single faulty, unreliable, or broken connection (e.g. between a counterbore and its respective via) may render an entire electrical system, for example of ATE, essentially useless.

The inventors have recognized and appreciated that providing for an interface PCB in which each plated counterbore corresponds to a plurality of vias (e.g. in support of the electrical connection between a corresponding single cable and a corresponding single pin) may yield a reliable electrical connection even in small-size, high-density applications.

Accordingly, some aspects of the present disclosure provide for an apparatus for facilitating reliable electrical connection through an interface PCB. The apparatus comprises an interface PCB having a first side and a second side, an interposer pad disposed on the first side of the interface PCB, a plated counterbore disposed on the second side of the interface PCB opposite the interposer pad, and a plurality of filled vias connecting the interposer pad to the plated counterbore through the interface PCB.

Some aspects of the present disclosure provide for a method of manufacturing an apparatus for facilitating reliable electrical connection through an interface PCB having a first surface and a second surface. The method comprises opening a plurality of through holes in the interface PCB wherein the first surface is parallel to the second surface and the plurality of through holes extend from the first surface through to the second surface, forming a plurality of vias by plating the plurality of through holes with an electrically conductive first material; filling the plurality of vias with a filler material, opening a counterbore on the first surface such that a first end of each of the plurality of vias interfaces with the counterbore, plating the counterbore with one or more electrically conductive layers, and disposing an electrically conductive interposer pad on the second surface opposite the counterbore such that a second end of each of the plurality of vias interfaces with the interposer pad.

Some aspects of the present disclosure provide for a system for providing interconnection in ATE. The system comprises a device, a plurality of cables, an interface PCB disposed between the device and the plurality of cables. The interface PCB comprises an array of interconnect structures, each comprising an interposer pad, a plated counterbore, and a plurality of filled vias connecting the interposer pad to the plated counterbore. The device includes a plurality of electrical connections coupled to the interposer pads of the array of interconnect structures. Each cable of the plurality of cables is coupled to a respective counterbore of the array of interconnect structures.

Following below are additional detailed descriptions of various features related to, and embodiments of, electrical connections comprising a plurality of vias operatively connected to a counterbore. It should be appreciated that various aspects described herein may be implemented in any of numerous ways. Examples of specific implementations are provided herein for illustrative purposes only. In addition, the various aspects and embodiments described below may be used alone or in any combination and are not limited to the combinations explicitly described herein.

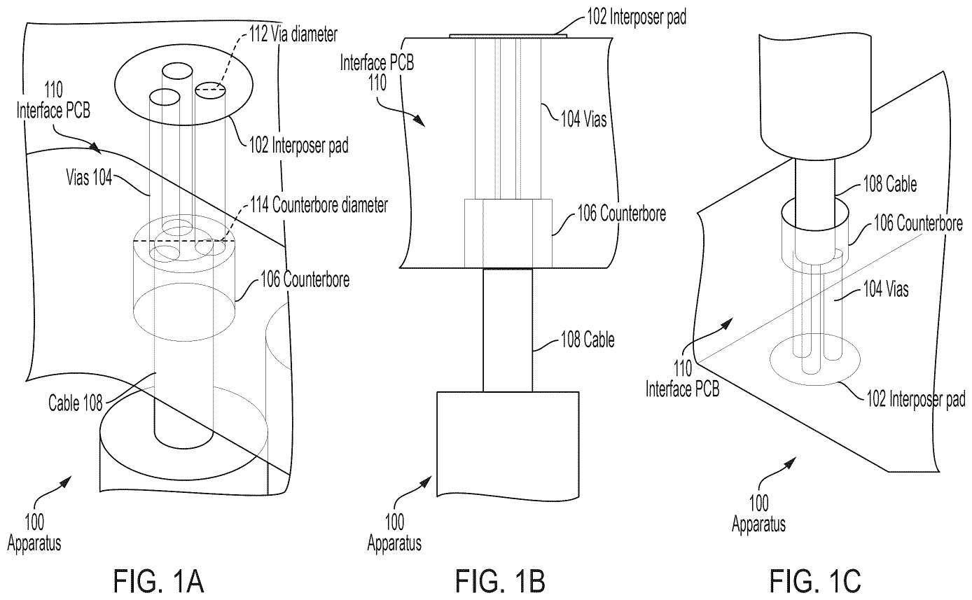

FIGS. 1A-1C are perspective views of an apparatus for facilitating reliable electrical connection according one embodiment of the present technology. As can be seen, the apparatus 100 (which may also be termed an “interconnect structure”) comprises an interposer pad 102, a plurality of vias 104, and a counterbore 106. Additionally, a cable 108 is disposed in the counterbore 106. The apparatus 100 is disposed in an interface PCB 110, as can be clearly seen in FIGS. 1B and 1C.

The interposer pad 102 is disposed on one side of the interface PCB 110. When the apparatus 100 is in use, a conductive member such as a pin may be disposed on or otherwise in electrical contact with the interposer pad 102 to establish an electrical connection therewith.

The interposer pad 102 may thus facilitate electrical connection with, for example, electrical test equipment or a device being tested by such equipment.

The plurality of vias 104 form an electrical connection between the interposer pad 102 and the counterbore 106. To enable this electrical connection, the vias 104 are plated with a conductive material such as copper, though it is understood that any suitable conductive material may be used. The vias 104 may be filled with a conducting or a non-conducting material; this filling may benefit the mechanical performance of the apparatus 100, for example by providing a flat (e.g. rather than cratered) surface on which the interposer pad 102 may be disposed or by ensuring that the interface PCB 110 between the vias is not overly fragile. Additionally, a subset of the vias 104 may be filled in such a way so as to reduce an electrical resistance through the PCB 110.

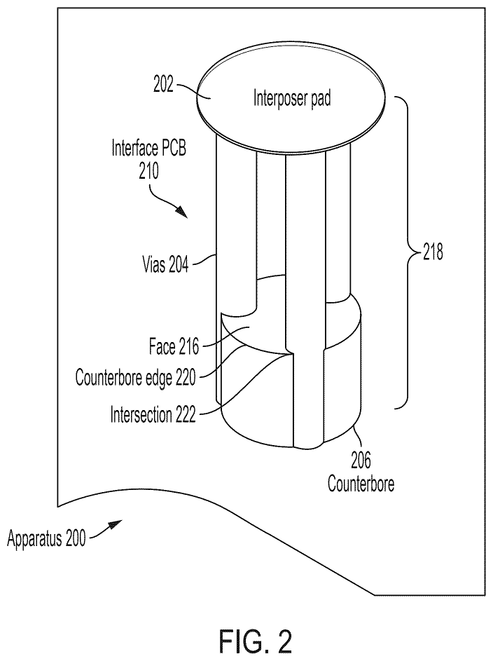

The vias 104 may have dimensions suited to the counterbore 106, the interface PCB 110, and to manufacturing capabilities of a manufacturer of the apparatus 100. The vias 104 may have a via diameter 112 which may, for example, be less than 20 mils (e.g. 15 mils, 10 mils, or as few mils as manufacturing capabilities allow), though the technology is not limited in this respect. The via diameter 112 may be determined based on considerations such as the number of vias 104 desired to be associated with the counterbore 106 and the structural integrity of the portions of the interface PCB 110 between the vias 104 (e.g. so as to not cause the interface PCB 110 to break during manufacturing). The vias 104 may extend through interface PCB 110, which may be of arbitrary thickness, with one end terminating at the interposer pad 102 and a second end terminating at the counterbore 106; however, the technology is not limited in this respect, as will be further described in conjunction with FIG. 2.

The vias 104 may be arranged in any configuration which allows the vias 104 to connect the interposer pad 102 to the counterbore 106; considerations such as geometric constraints and the structural integrity of the apparatus 100 may inform the positions of the vias 104. As shown, the plurality of vias 104 may be laterally offset from a centerline of the counterbore 106. Beneficially, the positions of the vias 104 may be determined relative to the counterbore 106 to increase the reliability of electrical connection (e.g. between the cable 108 and the interposer pad 102).

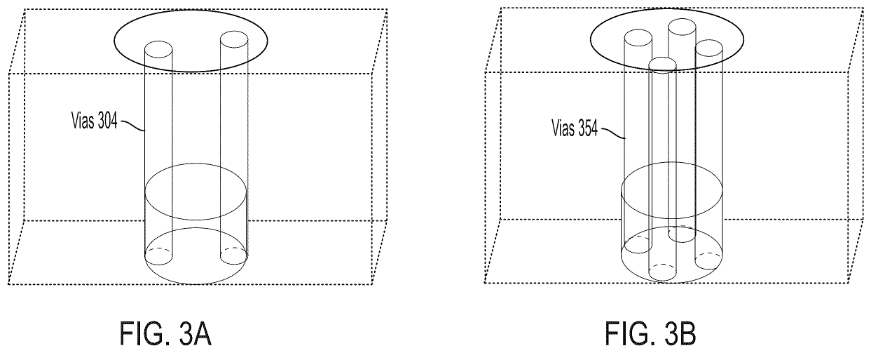

While in the embodiment shown in FIGS. 1A-1C there are three vias 104, the technology is not limited in this respect, as will be described below in conjunction with FIGS. 3A-3B. Additionally, while in the embodiment shown in FIGS. 1A-1C the vias 104 connect to a surface of the counterbore 106 which is parallel to the interposer pad 102, the technology is not limited in this respect, as will be described below in conjunction with FIG. 2.

The counterbore 106 is disposed on the opposite side of the interface PCB 110 from the interposer pad 102. The counterbore 106 may be plated with one or more layers of conductive material such as may facilitate an electrical connection with the vias 104, and thus between the cable 108 and the interposer pad 102. The counterbore 106 may have a counterbore diameter 114 which may, for example, be less than 50 mils (e.g. 40 mils, 33 mils, or as few mils as manufacturing capabilities allow and device requirements demand), though the technology is not limited in this respect. It is understood that the counterbore comprises a hole in the interface PCB 110 that may be configured to receive the cable 108 which may be attached (e.g. by soldering) and electrically connected to the counterbore 106. The cable 108 may thus (e.g. through an end of the cable 108 which is not shown in FIGS. 1A-1C) facilitate electrical connection with, for example, electrical test equipment or a device tested by such equipment.

FIG. 2 is a perspective view of an apparatus according to another embodiment of the present technology. Apparatus 200 is similar to apparatus 100 of FIGS. 1A-1C in that it comprises an interposer pad 202, a plurality of vias 204, a counterbore 206, and is disposed in an interface PCB 210. While apparatus 200 is not shown with a corresponding cable, it is understood that counterbore 206 may be configured to receive and be connected to a cable.

Apparatus 200 illustrates an embodiment of the present technology in which the plurality of vias 204 do not terminate at a face 216 of the counterbore 206 which is parallel to the interposer pad 202 but rather extend a length 218 between the interposer pad 202 and the opposite side of the interface PCB 210 while remaining electrically connected to the counterbore 206. Accordingly, at least a subset of the plurality of vias 204 may overlap with a counterbore edge 220 (e.g. such as may comprise a surface orthogonal to the interposer pad 202 and is not strictly confined to a “corner”) of the counterbore 206, forming at least one intersection 222 between the vias 204 and the counterbore edge 220.

The vias 204 may thus form an electrical connection with the counterbore 206 not simply at the face 216 but, additionally and/or alternatively, at the intersections 222. Because the plating of the counterbore 206 may be more reliable at the counterbore edge 220 (e.g. for reasons given above), the connection afforded by this embodiment may be more reliable than connections between the vias 204 and the face 216 alone.

However, depending on the degree of overlap, providing for vias 204 with overlap in this manner may require more surface area of the interface PCB 210 for the apparatus 200, which may be of concern in applications in which the interface PCB 210 comprises many such interconnect structures. The vias 204 may be positioned such that an intersection 222 exists between the vias 204 and the counterbore edge 220 without expanding the footprint of the apparatus 200 by disposing the vias 204 such that they are interior to the counterbore edge 220 and such that a perimeter of the vias 204 is tangent to the counterbore edge 220 so as to create one intersection 222 per via 204 so configured. While a configuration such as this may be advantageous in optimizing reliable electrical connection and avoiding the trade-off of increased footprint, manufacturing tolerances (e.g. discrepancies between a design and the manufactured product within a range considered acceptable or unavoidable by the manufacturer) may render it impractical in some instances.

FIGS. 3A-3B are perspective views of apparatuses according to additional embodiments of the present technology. Some features from foregoing figures are shown in FIGS. 3A-3B and not described again in detail here. FIG. 3A illustrates that, as described above in conjunction with FIGS. 1A-1C, an apparatus 300 may comprise two vias 304. FIG. 3B illustrates that, as described above in conjunction with FIGS. 1A-1C, an apparatus 350 may comprise four vias 354. It is understood that an apparatus may comprise five or more vias, or any suitable number of vias within relevant constraints (e.g. geometric, electrical, manufacturing, application-specific, and so forth).

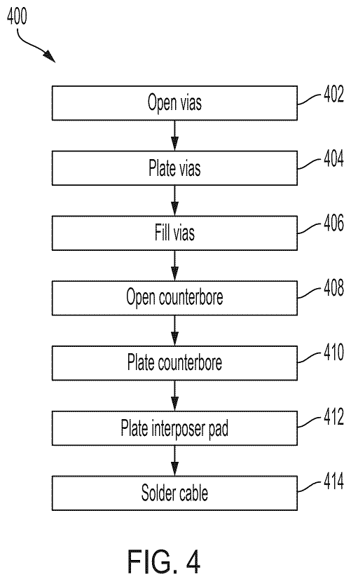

FIG. 4 is a flow chart illustrating a method 400 for manufacturing an apparatus according to some embodiments of the present technology. When manufacturing an apparatus as described according to this method 400, it is understood that a plurality of apparatuses (e.g. such as may be disposed within the same interface PCB) may be manufactured in parallel.

In step 402, a plurality of vias are opened in an interface PCB. Opening the vias may comprise drilling holes into the interface PCB, or opening holes in some other way. As part of this step 402, residue (e.g. non-conductive epoxy melted or degraded by drilling) may be removed by desmearing (e.g. chemical desmearing or plasma desmearing). Debris may also be removed by mechanical processes.

In step 404, the vias are plated with a conductive material (e.g. a material comprising copper). This plating may be performed by, for example, one or both of electroless deposition and electroplating. This step 404 may take place over several iterations of plating (e.g. multiple rounds of electroless deposition), for example, to create an even layer of conductive material within the vias and/or on other components of the interface PCB. At the conclusion of this step 404, the via may not be filled, but rather may be open along its centerline.

In step 406, the vias are filled with a conductive material (e.g. copper or silver) or a non-conductive material (e.g. epoxy). Filling the vias may improve the performance of the apparatus, and therefore of the interface PCB more broadly, by preventing fluids from becoming trapped in the via and introducing failures during subsequent processes (e.g. such as those which may require heating the PCB and thus may cause an expansion of trapped fluids). Additionally, filling the vias in step 406 may improve the mechanical strength of the apparatus.

Optionally, at this stage of the process, plating may be applied over the filled vias.

In step 408, a counterbore is opened (e.g. by drilling) on one side of the interface PCB such that the filled vias contact the counterbore. As in step 402, this step 408 may comprise processes to clear the interface PCB and the counterbore of residue and debris, including by mechanical or chemical processes. Opening the counterbore in step 408 may comprise creating an edge of the counterbore which overlaps with at least one of the plurality of vias.

In step 410, the counterbore is plated with one or more layers of conductive material. This plating may comprise, for example, a process of electroplating. The layers may comprise copper or may comprise a non-copper conductive material; in some embodiments, the counterbore may be plated with at least one layer of copper and (e.g. thereafter) at least one layer of a non-copper conductive material.

In step 412, an interposer pad is plated on a surface of the interface PCB opposite to the counterbore. The interposer pad comprises electrically conductive material and is positioned such that each via contacting a single counterbore contacts the same interposer pad (e.g. each via has one end contacting the counterbore and one end contacting the interposer pad).

In step 414, a cable may be soldered into the counterbore, thus connecting the cable to the counterbore with an electrically conductive material and creating an electrical connection between the cable and the interposer pad.

It is understood that the method 400 described above is not exclusive of other manufacturing processes (e.g. etching of undesired conductive material from the surface of the interface PCB) such as may take place before, concurrently with, or after the described steps. Also, the steps of method 400 may be re-ordered in alternative embodiments.

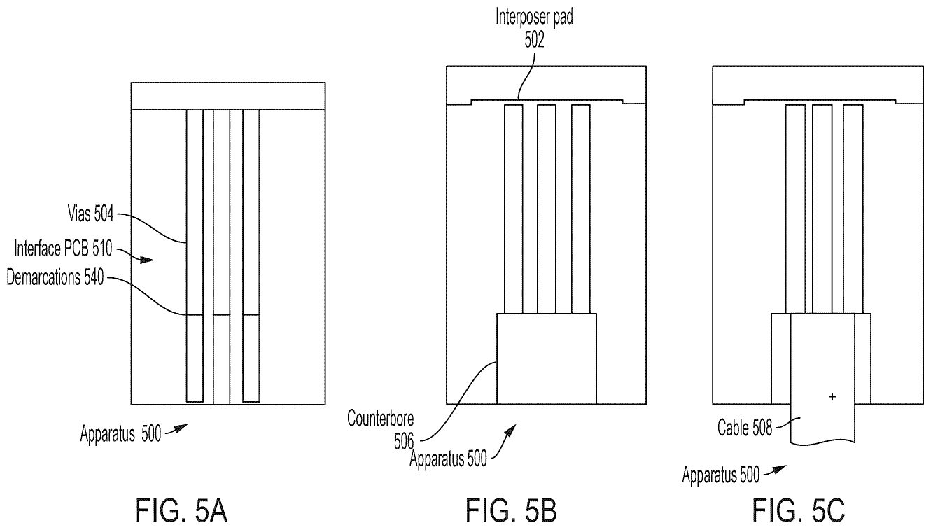

FIGS. 5A-5C are perspective views of an apparatus at different stages of manufacture according to steps illustrated in FIG. 4. FIG. 5A illustrates an apparatus 500 disposed in an interface PCB 510 in which vias 504 have been formed, plated, and filled according to steps 402, 404, and 406. It is understood that demarcations 540 serve to illustrate the eventual extent of a counterbore 506 and do not necessarily represent a physically distinct segment of the vias 504. FIG. 5B represents the apparatus 500 after the counterbore 506 has been opened and plated according to steps 408 and 410 and after an interposer pad has been plated according to step 412. FIG. 5C illustrates the apparatus 500 after a cable 508 has been inserted and soldered into the counterbore 506 according to step 414.

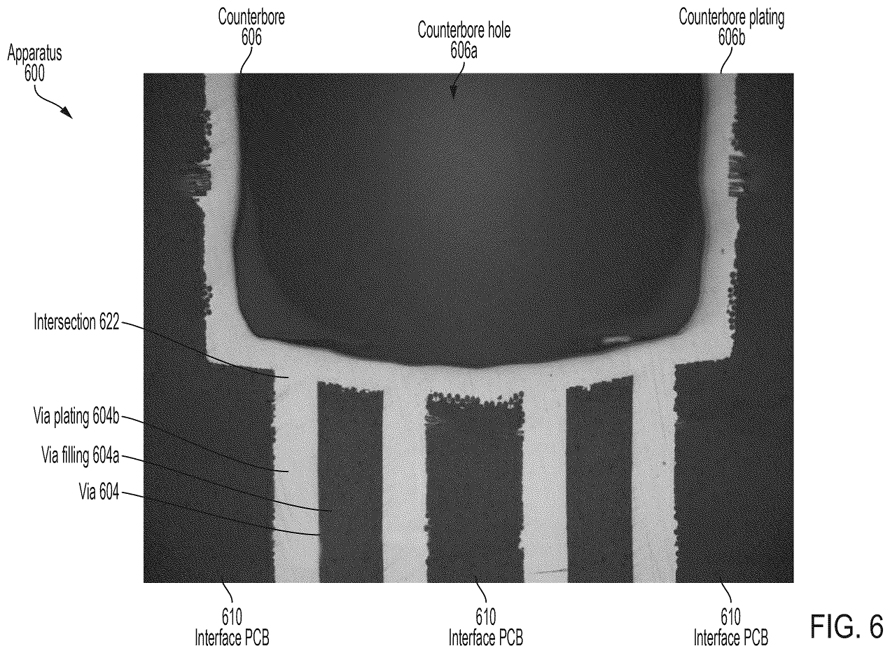

FIG. 6 is a cross-section of an apparatus 600 according to some embodiments of the present technology. In the cross-section of FIG. 6, two vias 604 can be seen disposed in an interface PCB 610 and electrically connected to a plated counterbore 606. While not shown in the figure, it is understood that apparatus 600 comprises an interposer pad analogous to that of embodiments described above.

As shown, each via 604 comprises a via filling 604a and a via plating 604b, and the counterbore 606 comprises a counterbore hole 606a and a counterbore plating 606b. The counterbore hole 606a is configured to receive a cable, which may, for example, be soldered into the counterbore hole 606a with solder creating an electrical connection between the cable and the counterbore plating 606b.

Each via plating 604b is configured to be electrically connected to the counterbore plating 606b at an intersection 622. As described above, manufacturing imperfections may result in intersections 622 which fail to establish an electrical connection between a given via plating 604b and the counterbore plating 606b (e.g. due to imperfect plating and/or physical deformation such as cracking of the via plating 604b and/or the counterbore plating 606b). However, because providing for a plurality of vias 604 yields a commensurately greater plurality of intersections 622 (and, as described above, intersections 622 at positions of the counterbore plating 606b which may be less likely to suffer from manufacturing imperfections), a reliable electrical connection between the counterbore plating 606b and the interposer pad of the apparatus 600 through at least one via plating 604b is substantially more likely to be established than if there was only one via 604. Additionally, it is understood that providing a plurality of vias 604 may result in mechanical advantages such as less separation force and/or vertical force being exerted on each via 604 when the apparatus 600 is under load.

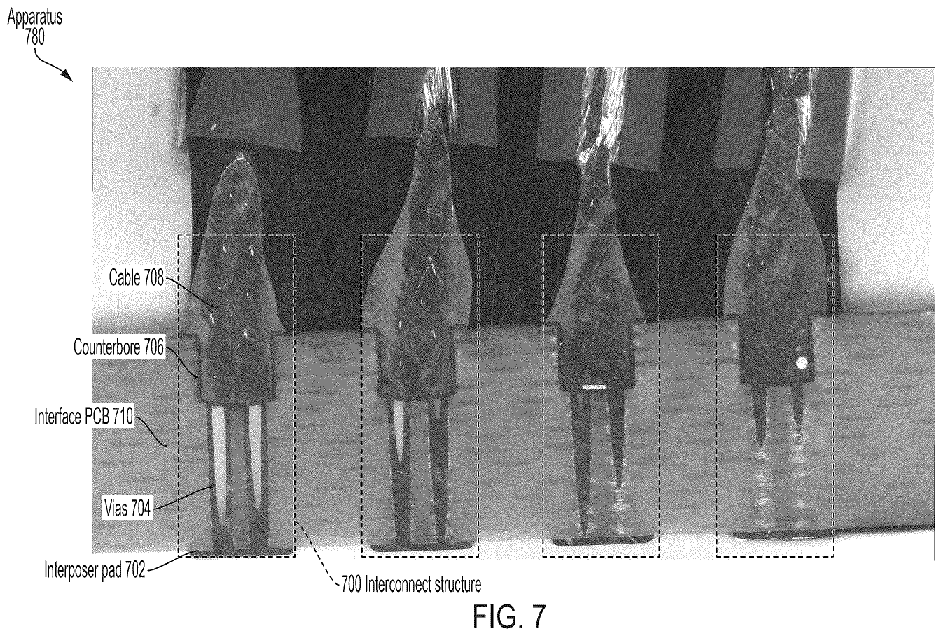

FIG. 7 is a cross-section of an apparatus 780 comprising a plurality of interconnect structures according to some embodiments of the present technology. In the cross-section of FIG. 7, four interconnect structures 700 can be seen disposed in the same interface PCB 710. Each interconnect structure 700 can be seen to comprise, in the plane of the cross-section, an interposer pad 702, two vias 704, and a counterbore 706 in which a cable 708 is disposed. (Additional vias may be present, but not visible in the plane of FIG. 7). The interface PCB 710 (of which only part is shown) may be, for example, a component in ATE, such that the interposer pads 702 and cables 708 may be configured to make electrical contact with other elements of a system of ATE or of a device to be tested by such a system of ATE.

An apparatus 780 may be manufactured which exhibits any of, and any combination of, the embodiments of the technology disclosed herein. For example, while only two vias 704 may be seen in the plane of the cross-section of FIG. 7, there may be a greater number of vias 704 associated with at least one of the interconnect structures 700. For example, three vias may be included in each interconnect structure 700. Additionally, while the vias 704 shown do not overlap with edges of the counterbores 706 shown, the technology is not limited in this respect, and in some embodiment an interconnect structure like that shown in FIG. 7 may instead have one or more vias overlapping with an edge of a counterbore.

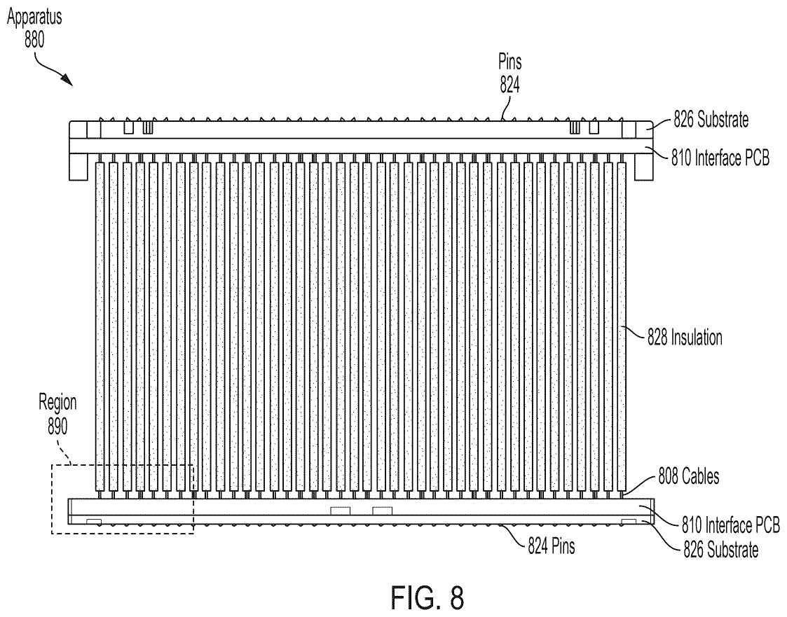

FIG. 8 is a perspective view of an apparatus according to some embodiments of the present technology. The apparatus 880 comprises two (e.g. a first and a second) interface PCB 810, a plurality of cables 808 (which may comprise insulation 828), and a plurality of pins 824 partially disposed in a substrate 826. As described above, the apparatus 880 may be a component of an ATE system.

Each interface PCB 810 comprises a plurality (e.g. an array) of interconnect structures according to embodiments of the technology disclosed herein (e.g. the interconnect structures may be embodiments analogous to one or more apparatus described in conjunction with the foregoing figures), and each of the cables 808 may be soldered at each end (e.g. into each of the interface PCB 810) to a respective counterbore of an interconnect structure. While the interconnect structures disposed within the interface PCB 810 cannot be seen in the perspective view of FIG. 8, it is understood that they may comprise any embodiment of the technology described herein. For example, the interconnect structures may comprise three filled vias; additionally, at least one via of the interconnect structures may overlap with an edge of the respective plated counterbores.

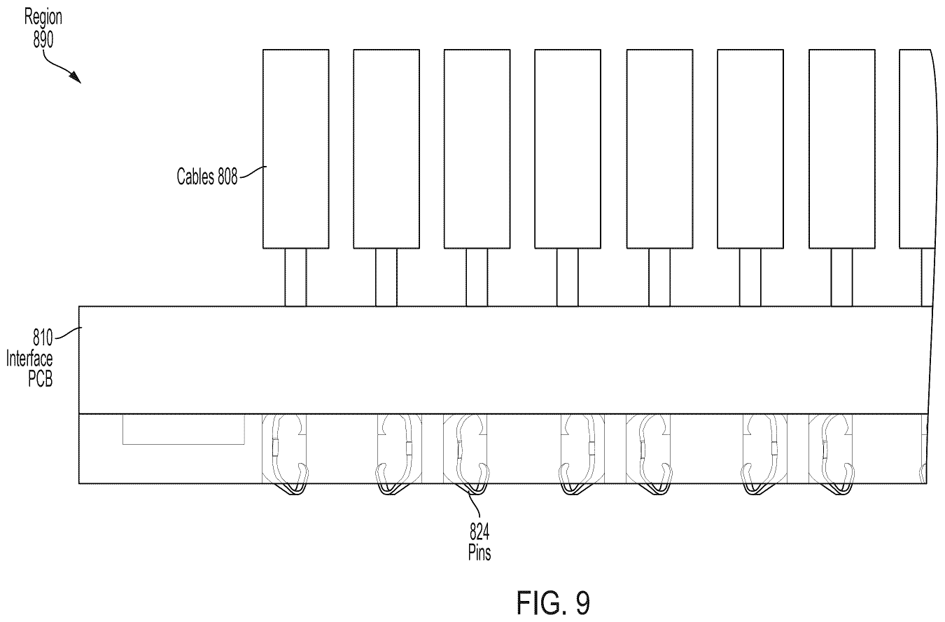

The plurality of pins 824 will be described more fully in conjunction with FIG. 9, which is a perspective view of region 890 of FIG. 8 with the substrate 826 made translucent.

FIG. 9 is a perspective view of a portion of the apparatus 880 of FIG. 8, and specifically of region 890 shown in FIG. 8. Because the substrate 826 has been made translucent in FIG. 9 for purposes of visibility, the pins 824 may be viewed to a greater extent than in FIG. 8.

As can be seen, the pins 824 are partially disposed in the substrate 826 and partially protruding from the substrate 826. On the end of the pins 824 proximate to the interface PCB the pins 824 may be in electrical contact with interposer pads associated with the array of interconnect structures disposed in the interface PCB 810. Accordingly (e.g. due to the electrical contact configured to be made between the pins 824 and the component termed “interposer pads” of the interconnect structures), the pins 824 may be termed an “interposer” in at least some embodiments. The end of the pins 824 distal to the interface PCB (e.g. including that portion of the pins 824 partially protruding from the substrate 826) may be configured to make electrical contact with an ATE system or with electrical devices to be tested by an ATE system.

The pins 824 shown are C-shaped compressive pins. However, it is understood that any suitable pin may be used for making an electrical connection between the interposer pads of the interconnect structures and a device to be coupled, as the technology is not limited in this respect. The selection of suitable pins 824 may be based on considerations such as which devices are intended to be electrically connected, cost, shape, and so forth.

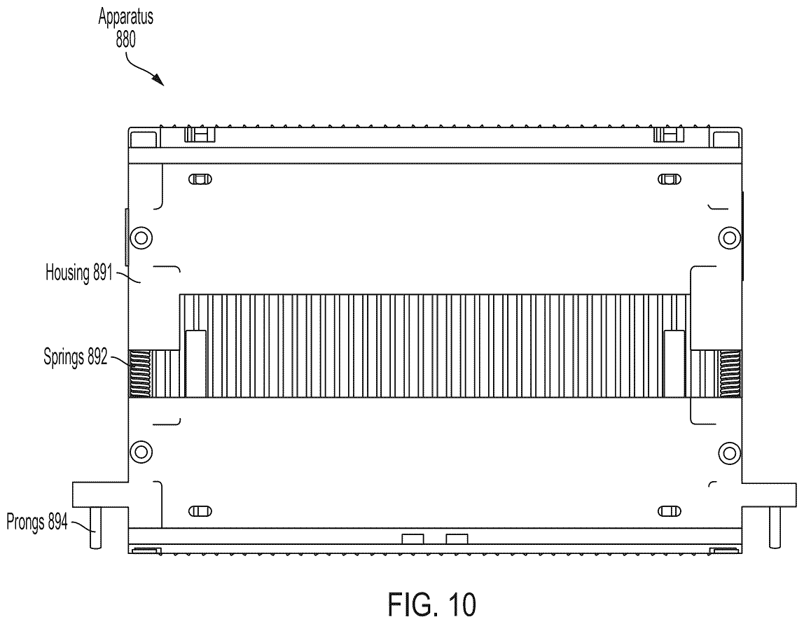

FIG. 10 is a perspective view of the apparatus of FIG. 8 with additional external components made visible. As can be seen, the apparatus 880 may comprise a housing 891.

The housing 891 may both increase the durability of the apparatus 880 and broaden its functionality. The housing 891 may serve to protect the apparatus 880 (e.g. from physical damage, contaminants such as dust, the influence of electric or magnetic fields, and so forth) and/or to facilitate integration of the apparatus 880 into a broader device (e.g. a system of ATE). The housing 891 may comprise conductive material and/or nonconductive material, may be comprised of a plurality of separable segments, and may be permanently or removably fastened (e.g. using fasteners such as screws) to the interface PCB 810.

As can be seen, the housing 891 may comprise springs 892 and prongs 894.

When the apparatus 880 is integrated into a broader device, the springs 892 may be compressed (e.g. in response to such a force as may also cause the cables 808 to deflect) in such a way to secure the apparatus 880 into the broader device and provide for an electrical connection between the pins 824 of the apparatus and the broader device. Additionally, the prongs 894, which may be alignment pins, may be engaged during such an integration to secure the apparatus 880 in place (e.g. by prevent lateral movement in a direction orthogonal to the compression of the springs 892).

Having described above several aspects of at least one embodiment, it is to be appreciated various alterations, modifications, and improvements will readily occur to those skilled in the art. Such alterations, modifications, and improvements are intended to be object of this disclosure. Accordingly, the foregoing description and drawings are by way of example only.

“Counterbore,” as used herein, includes what is conventionally known in the art as a “counterbore” as well as a “countersink,” as aspects of the present technology do not rely on distinguishing characteristics such as the flat profile of the counterbore. While some of the foregoing description has made reference to a surface of the counterbore which is, for example, parallel to the interposer pad, this terminology is used for convenience of explanation and the technology is not necessarily limited in this respect.

The indefinite articles “a” and “an,” as used herein in the specification and in the claims, unless clearly indicated to the contrary, should be understood to mean “at least one.” The phrase “and/or,” as used herein in the specification and in the claims, should be understood to mean “either or both” of the elements so conjoined, i.e., elements that are conjunctively present in some cases and disjunctively present in other cases. Multiple elements listed with “and/or” should be construed in the same fashion, i.e., “one or more” of the elements so conjoined. Other elements may optionally be present other than the elements specifically identified by the “and/or” clause, whether related or unrelated to those elements specifically identified.

As used herein in the specification and in the claims, the phrase “at least one,” in reference to a list of one or more elements, should be understood to mean at least one element selected from any one or more of the elements in the list of elements, but not necessarily including at least one of each and every element specifically listed within the list of elements and not excluding any combinations of elements in the list of elements. This definition also allows that elements may optionally be present other than the elements specifically identified within the list of elements to which the phrase “at least one” refers, whether related or unrelated to those elements specifically identified.

Also, the phraseology and terminology used herein is for the purpose of description and should not be regarded as limiting. The use of “including,” “comprising,” or “having,” “containing,” “involving,” and variations thereof herein, is meant to encompass the items listed thereafter and equivalents thereof as well as additional items.

What is claimed is:

1. An apparatus for facilitating reliable electrical connection through an interface printed circuit board (PCB), the apparatus comprising:
the interface PCB comprising:
a first side, and
a second side;
an interposer pad disposed on the first side of the interface PCB;
a plated counterbore disposed on the second side of the interface PCB opposite the interposer pad; and
a plurality of filled vias connecting the interposer pad to the plated counterbore through the interface PCB.

2. The apparatus of claim 1, wherein the plurality of filled vias comprise three vias.

3. The apparatus of claim 1, wherein the plated counterbore has an edge, and wherein at least one filled via of the plurality of filled vias overlaps the edge of the plated counterbore.

4. The apparatus of claim 1, wherein the plurality of filled vias are laterally offset from a centerline of the plated counterbore.

5. The apparatus of claim 1, wherein the plated counterbore has a diameter of less than 40 mils.

6. The apparatus of claim 5, wherein each of the plurality of filled vias has a via diameter, and the via diameter is less 15 mils.

7. The apparatus of claim 1, wherein the plurality of filled vias extend an entire length between the interposer pad and the second side of the interface PCB.

8. The apparatus of claim 1, wherein the plated counterbore has an edge and has a diameter less than 50 mils, and wherein the plurality of filled vias overlap the edge of the plated counterbore and each have a diameter less than 20 mils.

9. The apparatus of claim 1, further comprising a cable soldered into the plated counterbore.

10. The apparatus of claim 1, wherein the plurality of filled vias comprises a number of filled vias selected to reduce an electrical resistance through the interface PCB.

11. The apparatus of claim 1, wherein the plurality of filled vias are positioned relative to the plated counterbore to increase reliability of connection to a cable in the plated counterbore.

12. A method of manufacturing an apparatus for facilitating reliable electrical connection through an interface printed circuit board (PCB) having a first surface and a second surface, the method comprising:
opening a plurality of through holes in the interface PCB, wherein:
the first surface is parallel to the second surface, and
the plurality of through holes extend from the first surface through to the second surface;
forming a plurality of vias by plating the plurality of through holes with an electrically conductive first material;
filling the plurality of vias with a filler material;
opening a counterbore on the first surface such that a first end of each of the plurality of vias interfaces with the counterbore;
plating the counterbore with one or more electrically conductive layers; and
disposing an electrically conductive interposer pad on the second surface opposite the counterbore such that a second end of each of the plurality of vias interfaces with the interposer pad.

13. The method of claim 12, further comprising soldering a wire in the counterbore.

14. The method of claim 12, wherein plating the counterbore with one or more electrically conductive layers comprises:
plating the counterbore with a layer comprising copper; and
plating the layer comprising copper with a layer comprising a non-copper conductive material.

15. The method of claim 12, wherein opening the counterbore comprises creating an edge of the counterbore which overlaps with at least one of the plurality of vias.

16. The method of claim 12, wherein the electrically conductive first material comprises copper.

17. The method of claim 12, wherein the filler material is an electrically conductive material.

18. A system for providing electrical interconnection in automatic test equipment (ATE), the system comprising:
a device;
a plurality of cables;
an interface printed circuit board (PCB) disposed between the device and the plurality of cables, the interface PCB comprising:
an array of interconnect structures, each interconnect structure comprising:
an interposer pad,
a plated counterbore, and
a plurality of filled vias connecting the interposer pad to the plated counterbore,
wherein the device includes a plurality of electrical connections coupled to the interposer pads of the array of interconnect structures, and
wherein each cable of the plurality of cables is coupled to a respective counterbore of the array of interconnect structures.

19. The system of claim 18, wherein each of the plurality of cables is soldered to the respective counterbore of the array of interconnect structures.

20. The system of claim 18, wherein the plurality of filled vias comprises three filled vias.

21. The system of claim 20, wherein at least one of the three filled vias overlaps an edge of the plated counterbore.

22. The system of claim 18, wherein the interface PCB is a first interface PCB, and wherein the array of interconnect structures is a first array of interconnect structures, the system further comprising a second interface PCB comprising a second array of interconnect structures, each interconnect structure of the second array of interconnect structures including a plated counterbore, and wherein each cable of the plurality of cables is coupled to a respective plated counterbore of the second array of interconnect structures.

23. The system of claim 22, wherein the second array of interconnect structures comprises a plurality of interposer pads coupled to respective plated counterbores of the second array of interconnect structures by a respective plurality of filled vias.
